(19) United States
(12) Patent Application Publication
(10) Pub. No.: US 2023/0403889 A1
(43) Pub. Date: Dec. 14, 2023

(54) DISPLAY PANEL AND MANUFACTURING METHOD THEREOF

(71) Applicant: WUHAN CHINA STAR OPTOELECTRONICS SEMICONDUCTOR DISPLAY TECHNOLOGY CO., LTD., Wuhan (CN)

(72) Inventors: Likun Cheng, Wuhan (CN); Liang Sun, Wuhan (CN); Shijuan Yi, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 17/432,890

(22) PCT Filed: Jun. 4, 2021
(86) PCT No.: PCT/CN2021/098328

§ 371 Date: Dec. 1, 2022

(30) Foreign Application Priority Data
Jun. 4, 2021 (CN) 202110585366.X

(51) Int. Cl. H10K 59/124; H10K 59/12; H10K 59/80

(52) U.S. Cl. CPC H10K 59/124; H10K 59/1201; H10K 59/873

(57) ABSTRACT

The present application provides a display panel and a manufacturing method thereof. The display panel includes a plurality of display units. Each of the display units includes an island region and a chain region surrounding the island region. In at least one of the display units, the display panel includes an array substrate, a plurality of undercut structures, and an encapsulation layer. The undercut structures include a first undercut structure defined in the island region and a second undercut structure defined in the chain region.

### FIELD OF INVENTION

The present application is related to the field of display technology and specifically to a display panel and a manufacturing method thereof.

### BACKGROUND OF INVENTION

For a conventional stretchable panel, in order to facilitate tensile strain, a flexible substrate is scattered in shapes of islands, in which pixel circuits are distributed on the flexible islands, and lines connecting subpixels are distributed on a belt-shaped chain region surrounding the flexible islands. In order to enhance stretch ability of the stretchable panel, the flexible islands require individual encapsulation.

In a stretchable panel circuit, subpixel circuits are distributed on the flexible islands. In order to prevent damages caused by external factors such as water and oxygen, each of subpixel islands requires individual encapsulation.

However, current encapsulation technology is limited by a fine metal mask (FMM) spreading process, which is incapable of coping with a condition of a high pixel distribution density, and an increase in a pixel density of an organic light-emitting diode (OLED) stretchable panel is limited.

Therefore, in view of the problems of prior art, improvements are urgently needed.

### SUMMARY OF INVENTION

Purposes of the present application are to provide a display panel and a manufacturing method thereof to solve technical problems that a current display panel needs to be encapsulated separately when encapsulating subpixels, a blank frame region in a packaging process is large, gaps between the encapsulated subpixels are large, and a pixel density is not high.

In order to achieve the above purposes, the present application provides a display panel including an island region and a chain region. The chain region is connected to the island region and extending to an outer side of the island region. The display panel further includes: an array substrate provided with at least one subpixel and including a first organic layer; an undercut structures defined on the array substrate and recessed in the first organic layer of the array substrate; an encapsulation layer covering the array substrate and filled in the undercut structures. The undercut structures include a first undercut structure defined in the island region and surrounding the subpixel and a second undercut structure defined in the chain region.

Furthermore, the array substrate further includes an inorganic layer disposed on a side of the first organic layer and a second organic layer disposed on a side of the inorganic layer away from the inorganic layer. Each of the undercut structures sequentially penetrates the second organic layer and the inorganic layer and is recessed in the first organic layer. Each of the undercut structures is a groove structure.

Furthermore, the array substrate further includes a cathode layer disposed on a side of the second organic layer. Part of the cathode layer is disposed on a bottom of the first undercut structure. The encapsulation layer completely covers the cathode layer.

Furthermore, the island region includes a flexible base layer and a thin-film transistor disposed on a side of the flexible base layer facing the subpixel.

Furthermore, the chain region includes a flexible base layer, an organic filling layer disposed on a side of the flexible base layer facing the second undercut structure, and a connecting circuit distributed along an extending direction of the chain region. An end of the connecting circuit is connected to the island region.

Furthermore, the chain region is positioned between two adjacent island regions to connect the two adjacent island regions. The chain region includes a straight portion and a curved portion. The straight portion is connected to one of the two adjacent island regions. The curved portion is connected to the straight portion and is a stretchable portion. The second undercut structure is a strip structure, is defined in the chain region, and across the connecting circuit of the chain region.

Furthermore, the first undercut structure in the island region is ring-shaped. The ring-shaped first undercut structure is a closed-ring structure or an open-ring structure. One or more of the first undercut structures are defined in the island region and are positioned at a periphery of the island region adjacent to the chain region. One of the first undercut structures and another one of the first undercut structures adjacent to the one of the first undercut structures form a homocentric pattern when the island region is defined with a plurality of the first undercut structures.

Furthermore, the first undercut structure corresponding to an end of the island region connected to the connecting circuit is the closed-ring structure or the open-ring structure.

In order to achieve the above purposes, the present application further provides a manufacturing method of a display panel including steps of: forming an array substrate, wherein a first organic layer is formed on a flexible base layer, the array substrate includes an island region and a chain region, a subpixel is formed in the island region, a connecting circuit is formed in the chain region, and the chain region is connected to the island region and extends to an outer side of the island region; defining a plurality of undercut structures, wherein the undercut structures include a first undercut structure and a second undercut structure, the first undercut structure is positioned in the island region, and the second undercut structure is positioned in the chain region; and forming an encapsulation layer covering the undercut structures and the array substrate.

Furthermore, the step of forming the array substrate includes steps of: forming an inorganic layer in the first organic layer and forming a first through hole by a patterning process; and forming a second organic layer on the inorganic layer and forming a second through hole on the first through hole by the patterning process. The step of defining the plurality of undercut structures includes a step of supplying an etching gas into the second through hole and the first through hole to etch the first organic layer to define a groove in the first organic layer. Each of the undercut structures is formed by the groove, the first through hole, and the second through hole, and each of the undercut structures is a groove structure.

Technical effects of the present application are that the undercut structures are defined in the island region and the chain region in a display unit, the cathode layer is disposed in the first undercut structure in the island region, and then an entire encapsulation is then performed, without a requirement of individual encapsulation of each of the subpixels. This can further reduce gaps between any two adjacent subpixels, so as to increase a pixel density of the display panel, thereby enhancing stretch ability of the display panel.

### DESCRIPTION OF DRAWINGS

In order to describe technical solutions in the present application clearly, drawings to be used in the description of embodiments will be described briefly below. Obviously, drawings described below are only for some embodiments of the present application, and other drawings can be obtained by those skilled in the art based on these drawings without creative efforts.

FIG. 1 is a cross-sectional view of a display panel provided by an embodiment of the present application.

FIG. 2 is a schematic view of a first undercut structure including a closed-ring structure provided by an embodiment of the present application.

FIG. 3 is a cross-sectional view of undercut structures provided by an embodiment of the present application.

FIG. 4 is a schematic view of the first undercut structure including an open-ring structure provided by an embodiment of the present application.

FIG. 5 is a flowchart of a manufacturing method of the display panel provided by an embodiment of the present application.

### Reference Numeral

100: display unit, 101: island region, 102: chain region, 300: subpixel, 400: connecting circuit, 1: array substrate, 2: undercut structures, 3: cathode layer, 4: encapsulation layer, 11: glass substrate, 12: flexible base layer, 13: buffer layer, 14: gate insulating layer, 15: dielectric layer, 16: organic filling layer, 17: source and drain layer, 18: first organic layer, 19: inorganic layer, 110: second organic layer, 21: first through hole, 22: second through hole, 23: groove, 201: first undercut structure, and 202: second undercut structure.

### DETAILED DESCRIPTION OF EMBODIMENTS

The technical solution of the present application embodiment will be clarified and completely described with reference accompanying drawings in embodiments of the present application embodiment. Obviously, the present application described parts of embodiments instead of all of the embodiments. Based on the embodiments of the present application, other embodiments which can be obtained by a skilled in the art without creative efforts fall into the protected scope of the of the present application. In addition, it should be understood that specific implementations described here are only used to illustrate and explain the present application and are not used to limit the present application. In the present application, if no explanation is made to the contrary, orientation words such as “upper” and “lower” usually refer to upper and lower directions of a device in an actual use or a working state and specifically refer to drawing directions in drawings. Also, “inner” and “outer” refer to an outline of the device.

The present application provides a display panel and a manufacturing method thereof, the present application is further described in detail below with reference to accompanying drawings.

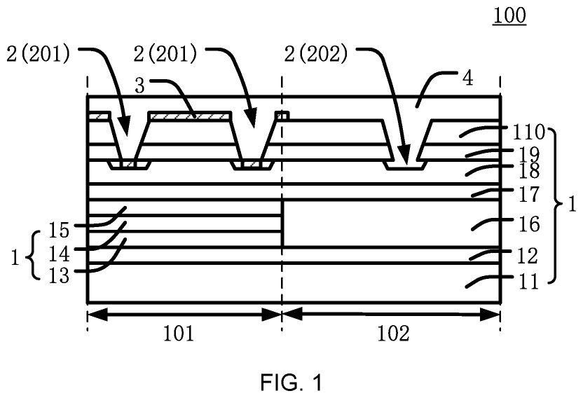

As shown in FIG. 1-3, the display panel provided by the present application includes an island region 101 and a chain region 102. The chain region 102 is connected to the island region 101 and extends to an outer side of the island region 101.

In the display unit 100, the display panel includes an array substrate 1, a plurality of undercut structures 2, and an encapsulation layer 4. The array substrate 1 is formed with at least one subpixel 300. The undercut structures 2 are defined on the array substrate 1 and recessed in the array substrate 1. The encapsulation layer 4 covers the array substrate 1, and is filled in the undercut structures 2. The undercut structures 2 include a first undercut structure 201 and a second undercut structure 202. The first undercut structure 201 is defined in the island region 101 and surrounds the subpixel 300, and the second undercut structure 202 is defined in the chain region 102.

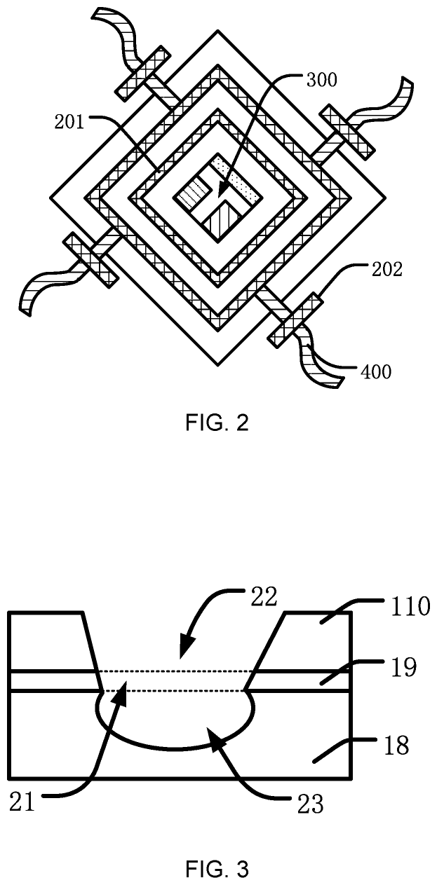

It should be explained that only one display unit 100 and one subpixel 300 are shown in FIGS. 1 and 2. However, in an embodiment, the array substrate 1 includes a plurality of the subpixels 300 corresponding to a plurality of the display units 100. That is to say, each of the display units 100 is provided with one subpixel 300, and the undercut structures 2 are defined around the subpixel 300, as shown in FIG. 2.

One display unit 100 is taken as an example to describe a structure of the display panel in an embodiment in detail below.

The array substrate 1 includes a glass substrate 11, a flexible base layer 12, a buffer layer 13, a gate insulating layer 14, a dielectric layer 15, an organic filling layer 16, a source and drain layer 17, a first organic layer 18, an inorganic layer 19, a second organic layer 110, and a cathode layer 3.

The glass substrate 11 is a hard substrate, which serves as a support and a substrate.

The flexible base layer 12 is disposed on a side of the glass substrate 11. A material of the flexible base layer 12 is a polyimide material with a thickness ranging from 5 μm to 10 μm. In this embodiment, a thickness of the flexible base layer 12 is preferably 6 μm.

The buffer layer 13 is disposed on a side of the flexible base layer 12 away from the glass substrate 11 and serves as a buffer. A material of the buffer layer 13 is an inorganic material. The inorganic material includes a single layer of silicon oxide or silicon nitride, or a multilayer structure.

The array substrate 1 further includes an active layer (not shown). The active layer is disposed on a side of the buffer layer 13 away from the flexible base layer 12. A material of the active layer is a semiconducting material. The semiconducting material includes at least one of indium gallium zinc oxide (IGZO), indium zinc titanium oxide (IZTO), or indium gallium zinc titanium oxide (IGZTO). The active layer provides circuit support for the display panel.

The gate insulating layer 14 is disposed on a side of the active layer away from the flexible substrate 12. A material of the gate insulating layer 14 is an inorganic material. The inorganic material includes silicon oxide or silicon nitride. The gate insulating layer 14 is arranged opposite to the active layer. The gate insulating layer 14 functions as an insulation to prevent short circuits among circuits inside the display panel.

The array substrate 1 further includes a gate layer (not shown). The gate layer is disposed on a side of the gate insulating layer 14 away from the active layer. A material of the gate layer is a metal material. The metal material includes molybdenum (Mo), aluminum (Al), copper (Cu), titanium (Ti), etc., an alloy, or a multilayer film structure. The gate layer is configured to introduce scanning signals from the circuits of the display panel.

The dielectric layer 15 is disposed on a side of the gate layer, the gate insulating layer 14, the active layer, and the buffer layer 13 away from the flexible base layer 12. The dielectric layer 15 is an interlayer insulating layer. A material of the dielectric layer 15 is an inorganic material. The inorganic material includes silicon oxide, silicon nitride, or a multilayer film structure, which has an insulating effect and prevents short circuits. A through hole is defined on the active layer. The through hole facilitates electrical connection between electrode layers such as the source and drain layer 17 and the active layer.

The organic filling layer 16 is positioned in the chain region 102. A deep hole is defined after removing the dielectric layer 15, the gate insulating layer 14, and the buffer layer 13 in the chain region 102. The organic filling layer 16 is formed after filling the deep hole with organic material. The organic filling layer 16 also serves as an insulation.

The source and drain layer 17 is disposed on a side of the dielectric layer 15 and the organic filling layer 16 away from the flexible base layer 12. A material of the source and drain layer 17 includes a metal material. The metal material includes molybdenum (Mo), aluminum (Al), copper (Cu), titanium (Ti), etc., an alloy, or a multilayer film structure. Part of the metal material is filled in the through hole. The source and drain layer 17 is electrically connected to the active layer (not shown) through the through hole to form a circuit conduction.

The first organic layer 18 is disposed on a side of the source and drain layer 17 away from the flexible base layer 12. The first organic layer 18 makes surfaces of film layers even, which facilitates subsequent attachments of other film layers, so as to prevent a detachment problem. In an embodiment of the present application, the first organic layer 18 is a flat layer, and a groove 23 is defined on the first organic layer 18, as shown in FIG. 3.

The inorganic layer 19 is disposed on a side of the first organic layer 18 away from the source and drain layer 17. The inorganic layer 19 is formed with a first through hole 21. The first through hole 21 corresponds to the groove 23. In an embodiment, a material of the inorganic layer 19 includes silicon oxide. The inorganic layer 19 is a passivation layer in this embodiment. The passivation layer serves as an insulation and isolates external water and oxygen.

The second organic layer 110 is disposed on a side of the inorganic layer 19 away from the first organic layer 18. In this embodiment, the second organic layer 110 is a pixel definition layer for defining a size of the island region 101. The second organic layer 110 is formed with a via hole. The via hole is defined opposite to the anode layer (not shown) on an upper surface of the inorganic layer 19. The via hole is configured to dispose the subpixel 300. That is to say, a hole transport layer, a hole injection layer, a luminescent material, an electron injection layer, an electron transport layer, and other film layers are all arranged in the via hole. The second organic layer 110 is formed with a second through hole 22. The second through hole 22 corresponds to the groove 23 and the first through hole 21. The second through hole 22, the first through hole 21, and the groove 23 form one of the undercut structures 2. That is to say, each of the undercut structures 2 is a groove structure.

Furthermore, each of the undercut structures 2 is defined in the display unit 100, is defined on a side of the array substrate 1 facing the encapsulation layer 4, and is recessed in the first organic layer 18, the inorganic layer 19, and the second organic layer 110. Specifically, each of the undercut structures 2 is a structure formed by penetrating the organic layer and the inorganic layer and followed by etching a film layer. In an embodiment, each of the undercut structures 2 includes the first through hole 21, the second through hole 22, and the groove 23 (shown in FIG. 3). That is to say, each of the undercut structures 2 is a groove structure.

As shown in FIGS. 1 and 2, the undercut structures 2 include the first undercut structure 201 and the second undercut structure 202. It can be understood that the first undercut structure 201 includes the first through hole 21, the second through hole 22, and the groove 23 shown in FIG. 3. Similarly, the second undercut structure 202 also includes the first through hole 21, the second through hole 22, and the groove 23 shown in FIG. 3.

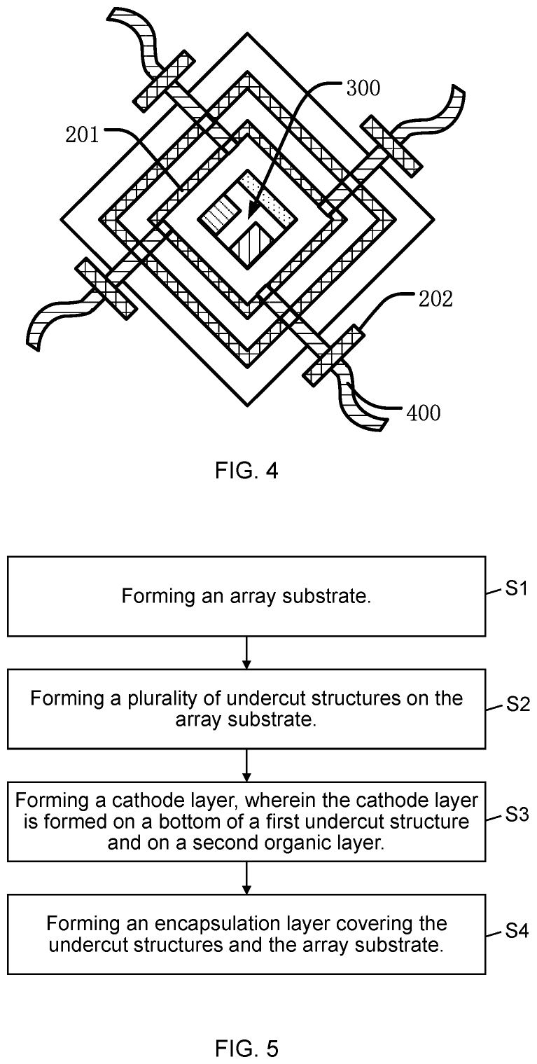

One or more of the first undercut structures 201 are defined in the island region 101 and positioned at a periphery of the island region 101 adjacent to the chain region 102. When a plurality of first undercut structures 201 are defined, one of the first undercut structures 201 and another one of the first undercut structures 201 adjacent to the one of the first undercut structures 201 form a homocentric pattern (shown in FIG. 2 or 4). That is to say, one of the first undercut structures 201 surrounds another one of the first undercut structures 201. A shape of each of the first undercut structures 201 can be a plurality of kinds of ring structures including shapes such as diamonds, squares, circles, etc. In this embodiment, the shape is preferably a diamond or a square. Therefore, more specifically, shortest distances between sides of the outer first undercut structure 201 and corresponding sides of the inner first undercut structure 201 are equal.

A pixel circuit is arranged in the island region 101. A connecting circuit is arranged in the chain region 102. The chain region 102 is positioned between two adjacent island regions 101 to connect the two adjacent island regions 101. The chain region 102 includes a straight portion and a curved portion. The straight portion is connected to the island region 101. The curved portion is connected to the straight portion. The curved portion is a stretchable portion.

The first undercut structure 201 is positioned in the island region 101. The first undercut structures 201 are the ring structures surrounding each of the subpixels 300. A periphery of each of the subpixels 300 is provided with one or more of the first undercut structures 201.

The first undercut structure 201 in the island region 101 is ring-shaped. The ring-shaped first undercut structure 201 is a closed-ring structure or an open-ring structure.

The first undercut structure 201 corresponding to an end of the connecting circuit connected to the island region 101 is a closed-ring structure or an open-ring structure.

In an embodiment, the first undercut structure 201 is a closed-ring structure (shown in FIG. 2). The closed-ring structure is the most preferable embodiment and can completely isolate the cathode layer in the island region 101.

In another embodiment, the first undercut structure 201 is an open-ring structure (shown in FIG. 4). In the open-ring structure, since the straight portion extends into the island region 101, the straight portion is in an open state, and the organic material is hollowed out from the straight portion, leaving only the inorganic material, while the organic material is prevented from absorbing water and oxygen that affect a waterproof performance of the display panel.

In an embodiment, the undercut structures 2 include two or more of the first undercut structures 201, and the two or more of the first undercut structures 201 have enhanced blocking effect.

It can be noted that, for the first undercut structure 201, an inner diameter of the groove 23 in the first organic layer 18 is greater than an inner diameter of the first through hole 21 and an inner diameter of the second through hole 22. Due to differences in manufacturing processes, the first through hole 21 and the second through hole 22 are formed in advance, and then the groove 23 in the first organic layer 18 is formed. Since an etching process is adopted, etching gas spreads to sidewalls of the first organic layer 18, which also provide more accommodating space for the cathode layer 3 to prevent excess cathode material from affecting film layers inside and outside of the ring structure formed by the first undercut structure 201.

The second undercut structure 202 is positioned in the chain region 102. The second undercut structure 202 is a strip structure. A number of the second undercut structure 102 can be one or more, can be defined on the straight portion adjacent to the island region 101, and can be defined on the curved portion.

Electrical signals in the island region 101 where each of the subpixels 300 are positioned is transmitted to an outside through the connecting circuit 400 positioned in the chain region 102 for a transmission of electrical signals with other subpixels 300. That is to say, in an embodiment, the second undercut structure 202 is positioned in the chain region 102 and is positioned in the chain region 102 between two adjacent island regions 101.

The second undercut structure 202 is an undercut film layer in a region where the connecting circuit 400 is positioned. The second undercut structure 202 can effectively prevent the chain region 102 from cracking toward the island region 101 when a cracking problem occurs, which greatly enhances the stretch ability of the display panel.

The cathode layer 3 is disposed on a side of the second organic layer 110 in the island region 101 away from the inorganic layer 19 and partially extends into the first undercut structure 201. In other words, part of the cathode layer 3 is arranged on the bottom of the first undercut structure 201.

Due to an existence of the first undercut structure 201, the cathode layer 3 can be confined to a corresponding one of the first undercut structures 201 without affecting the subpixel 300 in the first undercut structure 201, so that each of the subpixels 300 emits light separately, light emission of adjacent subpixels 300 are not affected, and cross-coloring and color-mixing are prevented from occurring between adjacent subpixels 300. In addition, during a manufacturing process of the cathode layer 3, a problem of coating deviation can also be prevented by accurate coating of masks.

The undercut structure 2, especially the first undercut structure 201 of the undercut structure 2, can enable the cathode layer 3 to be accurately coated, and also prevents cracks that occur during bending processes and other processes from spreading toward the subpixel 300. The stretch ability of the display panel is enhanced, film layers of the subpixel 300 are ensured to be unaffected, and light is emitted separately, thereby increasing a light-emitting performance of the display panel.

The encapsulation layer 4 is positioned in the island region 101 and the chain region 102, and is disposed on an upper surface of the second organic layer 110 and the cathode layer 3. The encapsulation layer 4 is filled into the undercut structure 2, and completely covers the cathode layer 3 to completely encapsulate the subpixel 300 and ensure that the subpixel 300 is not intruded by external water and oxygen.

The undercut structure 2 is defined on a top of the array substrate 1, such that forming deep holes from a top to the flexible base layer 12 is not required, and an interference of the etching gas on film layers on both sides during the etching process is prevented. In addition, relatively shallower grooves are also beneficial for preventing an interference to film layers during a flow of exhaust gas, thereby accelerating the etching process and increasing an etching efficiency.

The second undercut structure 202 is also simultaneously defined in the chain region 102 surrounding the island region 101, which can effectively prevent cracks that occur during bending processes and other processes from spreading toward the subpixel 300. The stretch ability of the display panel is enhanced, and the film layers of the subpixel 300 are protected, and the light-emitting performance of the subpixel 300 is ensured.

As shown in FIG. 5, the present application further includes a manufacturing method of a display panel including steps of S1-S4.

S1: Forming an array substrate 1. A first organic layer 18 is formed on a flexible base layer 12. The array substrate 1 is divided into an island region 101 and a chain region 102. A subpixel 300 is formed in the island region 101. A connecting circuit 400 is formed in the chain region 102. The chain region 102 is connected to the island region 101 and extends to an outer side of the island region 101. Specifically, step S1 includes manufacturing a glass substrate 11, the flexible base layer 12, a buffer layer 13, a gate insulating layer 14, a dielectric layer 15, an organic filling layer 16, a source and drain layer 17, a first organic layer 18, the inorganic layer 19, and a second organic layer 110.

The glass substrate 11 is provided. The glass substrate 11 is a hard substrate, which serves as a support and a substrate.

A layer of a polyimide material is coated on an upper surface of the glass substrate 11 to manufacture the flexible base layer 12, which serves as a support. A thickness of the flexible base layer 12 ranges from 5 μm to 10 μm. In this embodiment, the thickness of the flexible base layer 12 is preferably 6 μm.

A layer of an inorganic material is deposited on an upper surface of the flexible substrate 12 to manufacture the buffer layer 13, which serves as a buffer. The inorganic material includes a single layer of silicon oxide, silicon nitride, or a multilayer structure.

A layer of a semiconducting material is coated on an upper surface of the buffer layer 13, and followed by patterning to form an active layer. The semiconducting material includes at least one of indium gallium zinc oxide (IGZO), indium zinc titanium oxide (IZTO), or indium gallium zinc titanium oxide (IGZTO). The active layer provides circuit support for the display panel.

A layer of an inorganic material is deposited on an upper surface of the active layer to form the gate insulating layer 14. The inorganic material includes silicon oxide, silicon nitride, or a multilayer film structure, the gate insulating layer 14 is arranged opposite to the active layer. The gate insulating layer 14 serves as an insulation to prevent short circuits among the circuits inside the display panel.

A layer of a metal material is sputtered on an upper surface of the gate insulating layer 14 to form the gate layer. The metal material includes molybdenum (Mo), aluminum (Al), copper (Cu), titanium (Ti), etc., an alloy, or a multilayer film structure. The gate layer is configured to introduce scanning signals from the circuits of the display panel.

A layer of an inorganic material is deposited on upper surfaces of the gate layer, the gate insulating layer 14, the active layer, and the buffer layer 13 to form the dielectric layer 15, which is an interlayer insulating layer. The inorganic material includes silicon oxide, silicon nitride, or a multilayer film structure, which serves as an insulation and prevents short circuits. A through hole is defined on the active layer. The through hole facilitates electrical connection between electrode layers such as the source and drain layer 17 and the active layer.

In the chain region 102, a deep hole is defined after removing the dielectric layer 15, the gate insulating layer 14, and the buffer layer 13 in the chain region 102. The organic filling layer 16 is formed after filling the deep hole with organic material. The organic filling layer 16 also serves as an insulation.

A layer of a metal material is sputtered on upper surfaces of the dielectric layer 15 and the organic filling layer 16 to form the organic filling layer 17. The metal material includes molybdenum (Mo), aluminum (Al), copper (Cu), titanium (Ti), etc., an alloy, or a multilayer film structure. Part of the metal material is filled in the through hole. The source and drain layer 17 is electrically connected to the active layer (not shown) through the through hole to form a circuit conduction.

The first organic layer 18 is formed on an upper surface of the source and drain layer 17, and the first organic layer 18 makes surfaces of film layers even, which facilitates subsequent attachment of other film layers, so as to prevent a detachment problem.

A layer of a silicon oxide material is deposited on an upper surface of the first organic layer 18 to form the inorganic layer 19. The first through hole 21 is defined on the inorganic layer 19. The inorganic layer 19 serves as an insulation and isolates external water and oxygen

The second organic layer 110 is formed on an upper surface of the inorganic layer 19 for defining a size of the island region 101. The second organic layer 110 is formed with a via hole, and the via hole is defined opposite to the anode layer (not shown) on an upper surface of the inorganic layer 19. The via hole is configured to dispose the subpixel 300. That is to say, a hole transport layer, a hole injection layer, a luminescent material, an electron injection layer, an electron transport layer, and other film layers are all arranged in the via hole. The second through hole 22 is formed on the second organic layer 110 above the first through hole 21. The second through hole 22 is a mesa structure. That is to say, an inner diameter on a bottom of the second through hole 22 is less than an inner diameter at a top of the second through hole 22.

S2: Forming a plurality of undercut structures 2 on the array substrate 1. The undercut structures 2 include a first undercut structure 201 and a second undercut structure 202. The first undercut structure 201 is positioned in the island region 101. The second undercut structure 202 is positioned in the chain region 102.

The first undercut structure 201 is formed as a closed-ring structure or an open-ring structure.

When the first undercut structure 201 is the closed-ring structure, specific steps of manufacturing are as follows.

An etching gas is introduced into the second through hole 22 and the first through hole 21 to etch the first organic layer 18. The groove 23 is defined in the first organic layer 18. The groove 23, the first through hole 21, and the second through hole 21 form the undercut structure 2.

When the first undercut structure 201 is an open-ring structure, the organic material at the opening of the first undercut structure 201 needs to be hollowed out to prevent the organic material from absorbing water and oxygen that cause sealing failure of the display panel.

An inner diameter of the groove 23 in the first organic layer 18 is greater than an inner diameter of the first through hole 21 and an inner diameter of the second through hole 22. Due to differences in manufacturing processes, the first through hole 21 and the second through hole 22 are formed in advance, and then the groove 23 in the first organic layer 18 is formed. Since an etching process is applied, etching gas spreads to sidewalls of the first organic layer 18, which also provides more accommodating space for a cathode layer 3 to prevent the subsequent excess cathode material from affecting film layers inside and outside of the ring structure formed by the first undercut structure 201.

S3: Forming the cathode layer 3, wherein the cathode layer 3 is formed on a bottom of the first undercut structure 201 and on the second organic layer 110.

The cathode layer 3 formed on the film layers in the via hole and each film layer under the film layers form the subpixel 300. The subpixels 300 are configured to emit light.

Due to an existence of the first undercut structure 201, the cathode layer 3 can be confined to a corresponding one of the first undercut structures 201 without affecting the subpixel 300 in the first undercut structure 201, so that each of the subpixels 300 emits light separately, light emission of adjacent subpixels 300 are not affected, and cross-coloring and color-mixing are prevented from occurring between adjacent subpixels 300. In addition, during a manufacturing process of the cathode layer 3, a problem of coating deviation can also be prevented by accurate coating of masks.

The first undercut structure 201 is positioned in the island region 101. The first undercut structures 201 are the ring structures surrounding each of the subpixels 300. A periphery of each of the subpixels 300 can be surrounded by one or more of the first undercut structures 201. The first undercut structures 201 can ensure that the first undercut structures 201 have enhanced blocking effect. The second undercut structure 202 is positioned in the chain region 102. The second undercut structure 202 is a strip structure. Electrical signals in the island region 101 where each of the subpixels 300 is positioned are transmitted to an outside through a connecting circuit 400 positioned in the chain region 102 for a transmission of electrical signals with other subpixels 300.

The second undercut structure 202 is an undercut film layer in a region where the connecting circuit 400 is positioned. The second undercut structure 202 can effectively prevent the chain region 102 from cracking toward the island region 101 when a cracking problem occurs, which greatly enhances the stretch ability of the display panel. After a cathode material is restricted in a certain region, an encapsulation region is only required to be confined within the undercut structure 2, without consideration of an additional expansion caused by an offset of the cathode, so that an encapsulation design is simplified.

S4: Forming an encapsulation layer 4 covering the undercut structures 2 and the array substrate 1, so as to encapsulate the subpixels 300. Only one encapsulation process is required because of the existence of the first undercut structure 201 in the island region 101. The encapsulation layer formed in the first undercut structure 201 is equivalent to individual encapsulation of each of the subpixels 300. That is to say, a single process can achieve an effect of individual encapsulation, and gaps between any adjacent ones of the subpixels 300 are reduced, which is beneficial for increasing a pixel density of the display panel.

The undercut structure 2, especially the first undercut structure 201 of the undercut structure 2, can enable the cathode layer 3 to be accurately coated, and also prevents cracks that occur during bending processes and other processes from spreading toward the subpixel 300. The film layers of the subpixel 300 are ensured to be unaffected, and light is emitted separately, thereby increasing a light-emitting performance of the display panel.

The undercut structure 2 is defined on a top of the array substrate 1, such that forming deep holes from a top to the flexible base layer 12 is not required, and an interference of the etching gas on film layers on both sides during the etching process is prevented. In addition, relatively shallower grooves are also beneficial for preventing an interference to film layers during a flow of exhaust gas, thereby accelerating the etching process and increasing an etching efficiency.

The second undercut structure 202 is also simultaneously defined in the chain region 102 surrounding the island region 101, which can effectively prevent cracks that occur during bending processes and other processes from spreading toward the subpixel 300. The stretch ability of the display panel is enhanced, and the film layers of the subpixel 300 are protected, and the light-emitting performance of the subpixel 300 is ensured.

Technical effects of the manufacturing method of the display panel in this embodiment is that the undercut structures 2 are defined in the island region 101 and the chain region 102 in the display unit 100, and the first undercut structure 201 in the island region 101 is formed with the cathode layer 3, and an entire encapsulation is then performed, such that individual encapsulation of each of the subpixels 300 is not required. Due to a limitation of the masks of an encapsulation process, a blank encapsulation region is inevitable. Since only one mask is required for each encapsulation, only one blank encapsulation region occurs without a plurality of blank encapsulation regions, which further reduces the gaps between any adjacent ones of the subpixels 300 and increases the pixel density of the display panel.

The display panel and the manufacturing method thereof provided by the present application are described in detail above, the specific examples of this document are used to explain principles and embodiments of the present application, and the description of embodiments above is only for helping to understand the present application. Meanwhile, those skilled in the art will be able to change the specific embodiments and the scope of the present application according to the idea of the present application. In the above, the content of the specification should not be construed as limiting the present application. Above all, the content of the specification should not be the limitation of the present application.

What is claimed is:

1. A display panel, comprising:
an island region;
a chain region connected to the island region and extending to an outer side of the island region;
an array substrate provided with at least one subpixel and comprising a first organic layer;
a plurality of undercut structures defined on the array substrate and recessed in the first organic layer of the array substrate; and
an encapsulation layer covering the array substrate and filled in the undercut structures;
wherein the undercut structures comprise:
a first undercut structure defined in the island region and surrounding the subpixel; and
a second undercut structure defined in the chain region.

2. The display panel according to claim 1, wherein the array substrate further comprises:
an inorganic layer disposed on a side of the first organic layer; and
a second organic layer disposed on a side of the inorganic layer away from the first organic layer;
wherein each of the undercut structures sequentially penetrates the second organic layer and the inorganic layer and is recessed in the first organic layer, and each of the undercut structures is a groove structure.

3. The display panel according to claim 2, wherein the array substrate further comprises a cathode layer disposed on a side of the second organic layer, and part of the cathode layer is disposed on a bottom of the first undercut structure; and
the encapsulation layer completely covers the cathode layer.

4. The display panel according to claim 2, wherein the island region comprises:
a flexible base layer; and
a thin-film transistor disposed on a side of the flexible base layer facing the subpixel.

5. The display panel according to claim 1, wherein the chain region comprises:
a flexible base layer;
an organic filling layer disposed on a side of the flexible base layer facing the second undercut structure; and
a connecting circuit distributed along an extending direction of the chain region, wherein an end of the connecting circuit is connected to the island region.

6. The display panel according to claim 5, wherein the chain region is positioned between two adjacent island regions to connect the two adjacent island regions;
the chain region comprises a straight portion and a curved portion, the straight portion is connected to one of the two adjacent island regions, and the curved portion is connected to the straight portion and is a stretchable portion; and
the second undercut structure is a strip structure, is defined in the chain region, and across the connecting circuit of the chain region.

7. The display panel according to claim 6, wherein the first undercut structure in the island region is ring-shaped;
the ring-shaped first undercut structure is a closed-ring structure or an open-ring structure;
one or more of the first undercut structures are defined in the island region and are positioned at a periphery of the island region adjacent to the chain region; and
one of the first undercut structures and another one of the first undercut structures adjacent to the one of the first undercut structures form a homocentric pattern when the island region is defined with a plurality of the first undercut structures.

8. The display panel according to claim 7, wherein the first undercut structure corresponding to an end of the island region connected to the connecting circuit is the closed-ring structure or the open-ring structure.

9. A manufacturing method of a display panel, comprising steps of:
forming an array substrate, wherein a first organic layer is formed on a flexible base layer, the array substrate comprises an island region and a chain region, a subpixel is formed in the island region, a connecting circuit is formed in the chain region, and the chain region is connected to the island region and extends to an outer side of the island region;
defining a plurality of undercut structures, wherein the undercut structures comprise a first undercut structure and a second undercut structure, the first undercut structure is positioned in the island region, and the second undercut structure is positioned in the chain region; and
forming an encapsulation layer covering the undercut structures and the array substrate.

10. The manufacturing method of the display panel according to claim 9,
wherein the step of forming the array substrate comprises steps of:
forming an inorganic layer in the first organic layer and forming a first through hole by a patterning process; and
forming a second organic layer on the inorganic layer and forming a second through hole on the first through hole by the patterning process;
wherein the step of defining the plurality of undercut structures comprises steps of:
supplying an etching gas into the second through hole and the first through hole to etch the first organic layer to define a groove in the first organic layer; and
wherein each of the undercut structures is formed by the groove, the first through hole, and the second through hole, and each of the undercut structures is a groove structure.
